(19) United States
(12) Patent Application Publication
(10) Pub. No.: US 2009/0090392 A1
(43) Pub. Date: Apr. 9, 2009

(54) METHOD OF CLEANING A SEMICONDUCTOR WAFER

(75) Inventors: Ingrid Rink, Nijmegen (NL); Dirk M. Knotter, Nijmegen (NL); Gilbert P. A. Noij, Wijchen (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/293,253

(22) PCT Filed: Mar. 13, 2007
(86) PCT No.: PCT/IB2007/050851

§ 371 Date: Sep. 16, 2008

(30) Foreign Application Priority Data
Mar. 17, 2006 (EP) 06111305.6
Mar. 13, 2007 (IB) PCT/IB2007/050851

(51) Int. Cl. H01L 21/02; B08B 3/04

(52) U.S. Cl. 134/21; 134/33; 134/30; 134/25.4

(57) ABSTRACT

The invention provides a method of cleaning the surface (3) of a wafer (1), comprising a hot rinse step in which the wafer (1) is at a temperature that is at least 100C higher than room temperature, the wafer (1) is rotated around an axis perpendicular to the wafer surface (3) and water is dispensed on the wafer surface (3). Thereafter a first drying step is performed in which the wafer (1) is rotated around the axis perpendicular to the wafer surface (3) and in which the humidity of the environment is such that the water on the wafer surface (3) is partially removed while the wafer surface (3) remains covered with a film of water (13). The first drying step is followed by a second drying step, which removes the film of water (13) from the wafer surface (3). The method according to the invention advantageously reduces metal ion contamination on the wafer surface (3).

The invention relates to a method of cleaning a semiconductor wafer.

In semiconductor processing generally two techniques are applied to clean wafers: immersion in a bath comprising chemicals which clean the wafers and spraying chemicals, which have a cleaning effect, on the wafer. Both techniques are available in single wafer and batch processes. In the single wafer process the wafers are exposed to the chemicals during a shorter time period than in the batch process. The aim of the cleaning process is to remove as many unwanted particles as possible, such as for example organic contamination and metal ions.

In US 2004/0127044, a method of cleaning a single wafer is disclosed which reduces particle defects by minimizing the number of air-liquid interfaces that the wafer may experience during a single-wafer wet clean process, which is especially important for wafers with a hydrophobic surface. This is achieved by dispensing a liquid solution onto a horizontally positioned wafer in a single-wafer cleaning chamber at a flow rate, which is sufficient to cover the hydrophobic wafer surface with the liquid, while maintaining a wafer spin rate, which is sufficiently low to cover the hydrophobic surface with the liquid. Additionally, the method includes reducing or eliminating particle defects, especially silica agglomerates, on the wafer surface by minimizing reactions between the etch species and the wafer in a cleaning solution during a pH transition, for example by cooling the cleaning solution during the pH transition. Chelating agents are applied in a modified SC-1 (Standard Clean 1) cleaning solution to bind metal ion impurities, which are then removed together with the modified SC-1 solution. However, it appears that some metal ions, for example Al and Cr, are not bound by the chelating agent and hence remain as contaminants on the wafer.

It is an object of the invention to provide a method of cleaning a wafer surface, which reduces the metal ion contamination. The invention provides a cleaning method as claimed in claim 1. Advantageous embodiments are defined by the dependent claims.

The cleaning method according to the invention comprises the subsequent steps of:

a first step comprising a hot rinse in which the wafer is at a temperature that is at least 10° C. higher than room temperature, the wafer is rotated around an axis perpendicular to the wafer surface and water is dispensed on the wafer surface;

a second step in which the wafer (1) is rotated around the axis perpendicular to the wafer surface (3) and in which the evaporation rate of the water on the wafer surface (3) is such that the water is mainly removed from the wafer surface (3) by the rotation of the wafer(1) while the wafer surface (3) remains covered with a film of water (13); and

a third step, which removes the film of water from the wafer surface.

The first step removes metal contaminants from the wafer surface by spinning off excess water comprising the metal contaminants. The second step removes water comprising metal contaminants from the wafer surface by rotating the wafer while simultaneously preventing that the wafer surface dries in, which would disadvantageously leave metal contaminants on the wafer surface, by providing such a humidity that the evaporation rate of the water is reduced and the water is mainly removed from the wafer surface by centrifugal forces originating from the rotation of the wafer. The third step rapidly removes the remaining water from the wafer surface.

In an embodiment of the cleaning method according to the invention the first step is preceded by a cold rinse step in which the wafer is at room temperature and water is dispensed on the wafer surface. The cold rinse step provides for a reduction of the deposition of heavy metals, such as Fe.

In an embodiment of the cleaning method according to the invention the method is applied in a single wafer process. Preferably the first step is during a time period of 0.5 seconds to 90 seconds and the second step during a time period of 10 seconds to 100 seconds. Preferably the rotation speed during the first step and the second step is in this embodiment higher than 1000 rotations per minute.

In an embodiment of the cleaning method according to the invention the method is applied in a batch process. Preferably the first step is during a time period of 20 seconds to 300 seconds and the second step during a time period of 30 seconds to 300 seconds. Preferably the rotation speed during the first step and the second step in this embodiment is higher than 200 rotations per minute.

In an embodiment of the cleaning method according to the invention the water is dispensed on the wafer surface during the first step with a gradually decreasing flow rate. This advantageously reduces the thickness of the remaining water film, or carry-over layer, on the wafer surface, which is beneficial for the reduction of the number of metal contaminants that remain on the wafer surface.

In an embodiment of the cleaning method according to the invention a nitrogen gas flow controls the humidity of the environment, which gas flow is higher during the third step than during the second step.

These and other aspects of the method of the invention will be further elucidated and described with reference to the drawings, in which:

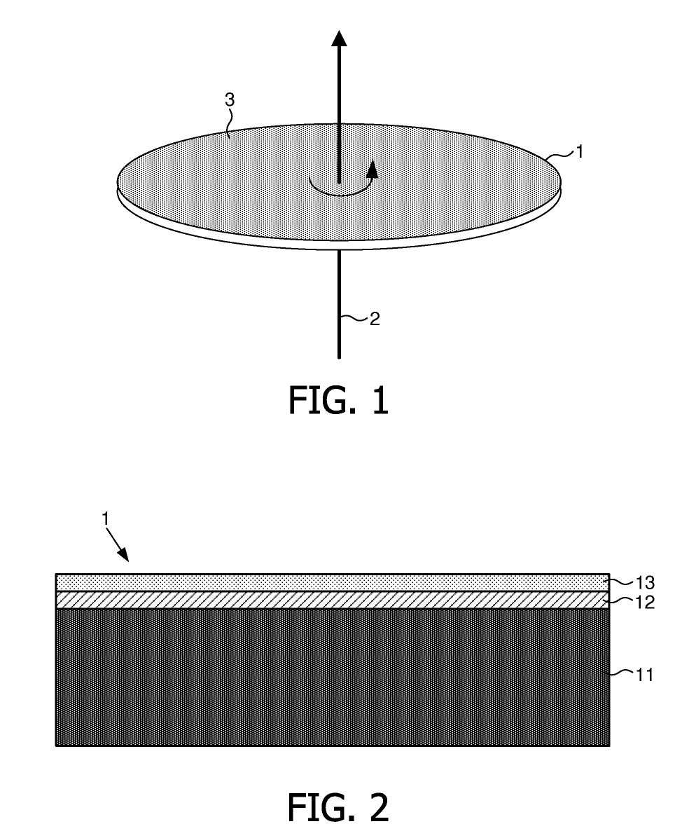

FIG. 1 is a view of a rotating wafer; and

FIG. 2 is a diagrammatic cross-sectional view illustrating the layers involved in an embodiment of a method according to the invention.

The Figures are not drawn to scale. In general, identical components are denoted by the same reference numerals in the Figures.

During a cleaning process there are several sources that contribute to the total metal ion concentration on a silicon wafer. A first source of metal ions is absorption of metal ions in a silica (SiOH) layer, comprising silicon dioxide and water, which is extending over the semiconductor wafer. This occurs if the silica layer is a natural oxide layer or chemically grown with for example ozone or sulfuric acid-based cleaning solutions. This silica layer contains a lot of water and is permeable for some metal ions. Metal ions present in this silica layer will be hard to remove and mostly only etching of the silica layer can remove the metal ions, but in some technologies this is no option. It should be noted that silicon wafers with a thermally grown silicon dioxide layer hardly absorb metal ions. A second source of metal ions is the surface of the silica layer, which comprises a lot of adsorption sites. There are several ways for metal ions to adsorb on the surface, one of which is for example an ion exchange reaction with Si—OH groups. A third source of metal ions originates from a drying process step after a rinse step, wherein the wafers are dried in an immersion process by pulling the wafers out of the liquid, for example de-ionized (DI) water, or in a spinning process by a rotation of the wafer which spins off the excess of liquid. On hydrophilic silica surfaces, a so-called carry-over layer will remain which dries in and the contaminants present in this carry-over layer are in this way deposited on the surface of the silica layer. In the spinning process, the carry-over layer is reduced by centrifugal forces and by evaporation of the liquid at the same time. Evaporation will lead to contamination left on the surface, and centrifugal forces will remove the liquid with the contaminants from the wafer.

FIG. 1 illustrates a process of cleaning the surface of a silicon wafer (1) according to the invention, in this case with a spray apparatus applied to single wafers. The wafer (1) is placed in a horizontal orientation and is rotated during the cleaning process around an axis (2) that is perpendicular to the center of the wafer surface. Particles on the wafer (1) are removed, in part, by applying cleaning solutions and rinses to the surface of the wafer (1). The cleaning solutions are based on the RCA cleaning method: APM (Ammonia hydroxide-hydrogen Peroxide-water Mixture, NH₄OH/H₂O₂/H₂O) or SC-1 (Standard Clean 1), followed by a rinse with DI-water, and then by HPM (Hydrochloric acid-hydrogen Peroxide-water Mixture, HCl/H₂O₂/H₂O) or SC-2 (Standard Clean 2). APM is a cleaning solution used primarily to remove particles from the surface of the wafer (1) and is also capable of removing surface organics. It forms a chemical oxide (hydrophilic surface) on the surface of the wafer (1). HPM is a cleaning solution used primarily to remove metallic contaminants and it avoids the deposition of metals.

As is shown in a cross-sectional view of the wafer (1) in FIG. 2, a chemical oxide layer (12) is formed on the surface of the silicon wafer (1) by the APM cleaning step. To remove metal ions that are adsorbed on the surface of the silicon wafer (1) or on the surface of the chemical oxide layer (12), a hot rinse step is applied in which DI-water is dispensed over the wafer surface thereby creating a carry-over layer (13) comprising water and metal ion contaminants. The wafer (1) is rotated with a high rotation speed, which depends on the specifications of the applied equipment and is for example 400 RPM to 10000 RPM (Rotations Per Minute) and preferably between 1000 RPM and 3000 RPM, to spin off more water with metal ions from the surface of the wafer (1). The temperature of the wafer (1) during the hot rinse step is at least 10° C. higher than room temperature, for example 40° C. The hot rinse step is relatively short and between 0.5 and 90 seconds, typically around 5 seconds, depending on, amongst others, optimization of the capacity of the rinsing equipment and uniformity of the removal of metal ions over the whole surface of the wafer (1). The hot rinse step provides for a thinner carry-over layer (13) on the surface of the wafer (1), and hence for a reduction of metal ions that are left on the wafer surface before the drying of the wafer (1) starts. Preferably the flow rate of the DI-water is very low at the end of the hot rinse step, by which an even thinner carry-over layer (13) is obtained. A preferred way to obtain the low DI-water flow is to decrease the flow rate of the DI-water gradually during the hot rinse step, for example linearly from 2 liters per minute to 150 milliliters per minute.

In an embodiment the hot rinse step may be preceded by a cold rinse step in which the temperature of the wafer (1) is at room temperature and DI-water is dispensed over the rotating wafer (1) with a flow rate which is for example 2 liters per minute. The cold rinse step provides for a reduced deposition of heavy metal ions on the surface of the wafer (1), such as, for example, Fe.

After the hot rinse step the wafer (1) is dried in a controlled way. A first drying step is performed in a relatively high humidity environment, which reduces the evaporation rate of the water in the carry-over layer (13). This means that, because the wafer (1) is rotated at a high rotation speed and the evaporation rate of the water in the carry-over layer (13) is reduced, more water will be removed, or spun, from the wafer (1) than at a lower rotation speed thereby reducing the metal ion contamination on the wafer (1). It is important that the surface of the wafer (1) is covered with a (thin) film of water during this hot rinse step to avoid a drying in of the carry-over layer (13) thereby leaving an increasing number of metal ions on the wafer surface. The high rotation speed of the wafer (1) depends on the specifications of the applied equipment and is for example 400 RPM to 10000 RPM and preferably between 1000 RPM and 3000 RPM. The surface of the wafer (1) remains covered with a thin carry-over layer (13) comprising water and the humidity is kept high for example by applying a humid nitrogen gas flow or a shield plate, thereby creating a semi-closed environment, in combination with a low nitrogen gas flow. Typically the humidity of the environment is between 80% and 100%, and preferably 95%, which is comparable to the humidity during the preceding hot rinse step. The first drying step is between 10 and 100 seconds, depending on, amongst others, optimization of the capacity of the applied cleaning equipment.

Finally, a second drying step provides for a drying of the wafer (1) as fast as possible. For this purpose a high Nitrogen gas flow is applied, the wafer (1) is heated, which reduces the humidity of the environment, and the wafer (1) is rotated at a high speed, which depends on the specifications of the applied equipment and is for example between 400 RPM to 10000 RPM.

Experimental results of the method according to the invention show a decrease of the metal ion contamination of a factor 2 or more with respect to the common cleaning methods.

The cleaning method according to the invention can also be applied in so-called batch processes in which at least one wafer cassette, comprising the to be cleaned wafers, is placed in a batch cleaning apparatus. The maximum obtainable rotation speed of the wafers is usually smaller when using the batch cleaning apparatus than when using the single wafer spray apparatus. For example a high rotation speed that can be obtained with the batch cleaning apparatus is higher than 200 RPM. In case of the batch cleaning apparatus the time of the hot rinse step is between 20 seconds to 300 seconds and preferably 90 seconds, and the time of the first drying step is between 30 seconds and 300 seconds. Furthermore, in this case the time of the optional cold rinse step is between 60 seconds and 700 seconds.

In summary, the invention provides a method of cleaning the surface of a wafer, comprising a hot rinse step in which the wafer is at a temperature that is at least 10° C. higher than room temperature, the wafer is rotated around an axis perpendicular to the wafer surface and water is dispensed on the wafer surface. Thereafter a first drying step is performed in which the wafer is rotated around the axis perpendicular to the wafer surface and in which the humidity of the environment is such that the water on the wafer surface is partially removed while the wafer surface remains covered with a film of water. The first drying step is followed by a second drying step, which removes the film of water from the wafer surface. The method according to the invention advantageously reduces metal ion contamination on the wafer surface.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of other elements or steps than those listed in a claim. The word “a” or “an” preceding an element does not exclude the presence of a plurality of such elements.

1. A method of cleaning a surface of a wafer, the method comprising the. subsequent steps of:
a first step comprising a hot rinse in which the wafer is at a temperature that is at least 10° C. higher than room temperature, the wafer is rotated around an axis perpendicular to the wafer surface and water is dispensed on the wafer surface;
a second step in which the wafer is rotated around the axis perpendicular to the wafer surface and in which the evaporation rate of the water on the wafer surface is such that the water is mainly removed from the wafer surface by the rotation of the wafer while the wafer surface remains covered with a film of water; and
a third step which removes the film of water from the wafer surface.

2. A method of cleaning a wafer surface as claimed in claim 1, wherein the first step is preceded by a cold rinse step in which the wafer is at room temperature and water is dispensed on the wafer surface.

3. A method of cleaning a wafer surface as claimed in claim 1, wherein the method is applied in a single wafer process.

4. A method of cleaning a wafer surface as claimed in claim 3, wherein the first step is during a time period of 0.5 seconds to 90 seconds, and the second step during a time period of 10 seconds to 100 seconds.

5. A method of cleaning a wafer surface as claimed in claim 3, wherein during the first step and the second step the wafer is rotated at a rotation speed higher than 1000 rotations per minute.

6. A method of cleaning a wafer surface as claimed in claim 1, wherein the method is applied in a batch process.

7. A method of cleaning a wafer surface as claimed in claim 6, wherein the first step is during a time period of 20 seconds to 300 seconds, and the second step during a time period of 30 seconds to 300 seconds.

8. A method of cleaning a wafer surface as claimed in claim 6, wherein during the first step and the second step the wafer is rotated at a rotation speed higher than 200 rotations per minute.

9. A method of cleaning a wafer surface as claimed in claim 1, wherein the water is dispensed on the wafer surface during the first step with a gradually decreasing flow rate.

10. A method of cleaning a wafer surface as claimed in claim 1, wherein a nitrogen gas flow controls the humidity of the environment which gas flow is higher during the third step than during the second step.
